(19) United States
(12) Patent Application Publication
(10) Pub. No.: US 2012/0228574 A1
(43) Pub. Date: Sep. 13, 2012

(54) VARIABLE RESISTIVE MEMORY DEVICE AND METHOD OF MANUFACTURING THE SAME

(76) Inventors: SANG-SU PARK, Seoul (KR); Jaehee Oh, Seongnam-si (KR); Jung-In Kim, Seoul (KR)

(21) Appl. No.: 13/405,990

(22) Filed: Feb. 27, 2012

(30) Foreign Application Priority Data
Mar. 11, 2011 (KR) 10-2011-0022109

(51) Int. Cl. H01L 45/00

(52) U.S. Cl. 257/2; 257/E45.003

(57) ABSTRACT

A variable resistive memory device includes a substrate comprising a cell region and a peripheral region, a word line extending in a first direction formed on the substrate of the cell region, a switching element formed on the word line, a variable resistance layer formed on the word line, and at least one transistor comprising a gate stack, the gate stack formed on the substrate of the peripheral region, wherein the word line comprises a metal layer formed at a same level as the gate stack.

### CROSS-REFERENCE TO RELATED APPLICATIONS

This U.S. non-provisional patent application claims priority under 35 U.S.C. §119 of Korean Patent Application No. 10-2011-0022109, filed on Mar. 11, 2011, the entire contents of which are hereby incorporated by reference.

### BACKGROUND

1. Technical Field

The present disclosure relates to a variable resistive memory device and a method of manufacturing the same, and more particularly, to a variable resistive memory device including a variable resistance layer and a method of manufacturing the same.

2. Discussion of Related Art

A variable resistive memory device is a type of non-volatile memory. The variable resistive memory device may store data using different resistance states in accordance with a phase transition of chalcogenide type compound constituting a variable resistance layer. The variable resistive memory device includes a plurality of unit cells. Each unit cell of the variable resistive memory device may include one variable resistance layer and one switching device.

### SUMMARY

According to an exemplary embodiment of the present disclosure, a variable resistive memory device includes a substrate comprising a cell region and a peripheral region, a word line extending in a first direction formed on the substrate of the cell region, a switching element formed on the word line, a variable resistance layer formed on the word line, and at least one transistor comprising a gate stack, the gate stack formed on the substrate of the peripheral region, wherein the word line comprises a metal layer formed at a same level as the gate stack.

According to an exemplary embodiment of the present disclosure, a method of manufacturing a variable resistive memory device includes forming a substrate having an active region, the substrate comprising a cell region and a peripheral region, forming a device isolation layer on the substrate, wherein the active region of the cell region is recessed, forming, simultaneously, a word line extending in a first direction on the device isolation layer of the cell region and a gate stack on the active region of the peripheral region, and forming, sequentially, a switching element and a variable resistance layer on the word line.

According to an exemplary embodiment of the present disclosure, a variable resistive memory device including a substrate comprising a cell region and a peripheral region, a word line formed on the substrate of the cell region, a plurality of phase change memory cells connected to the word line, and at least one transistor comprising a gate stack, the gate stack formed on the substrate of the peripheral region, wherein the word line and the gate stack are formed of different portions of a same metal layer.

### BRIEF DESCRIPTION OF THE FIGURES

Exemplary embodiments of the present disclosure will be apparent from the following description and accompanying drawings in which like reference characters refer to the same parts throughout the different views. The drawings are not necessarily to scale, emphasis instead being placed upon illustrating exemplary embodiments. In the drawings, the thickness of layers and regions may be exaggerated for clarity.

FIG. 1 is a top plan view illustrating a variable resistive memory device in accordance with an exemplary embodiment of the present disclosure.

FIG. 2 is an equivalent circuit diagram illustrating a cell array in a cell area of FIG. 1.

FIG. 3 is a layout of the variable resistive memory device of FIG. 1.

FIGS. 4A and 4B are cross sectional views taken along the lines I-I′ and II-II′ of FIG. 1 respectively.

FIGS. 5A through 19A and FIGS. 5B through 19B are cross sectional views illustrating a method of manufacturing a variable resistive memory device having the cross sections of FIG. 4A and FIG. 4B, respectively.

### DETAILED DESCRIPTION OF EXEMPLARY EMBODIMENTS

Exemplary embodiments of the present disclosure will be described below in more detail with reference to the accompanying drawings. The present disclosure may, however, be embodied in different forms and should not be constructed as limited to embodiments set forth herein. Rather, exemplary embodiments are provided so that this disclosure will be thorough and complete, and will fully convey the scope of the inventive concept to those skilled in the art. Like numbers refer to like elements throughout.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. In the drawings, the thickness of layers and regions may be exaggerated for clarity. It will also be understood that when an element such as a layer, region or substrate is referred to as being “on” or “onto” another element, it may lie directly on the other element or intervening elements or layers may also be present.

Embodiments of the inventive concept may be described with reference to cross-sectional illustrations, which are schematic illustrations of idealized embodiments of the present disclosure. As such, variations from the shapes of the illustrations, as a result, for example, of manufacturing techniques and/or tolerances, are to be expected. Thus, embodiments of the present disclosure should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present disclosure.

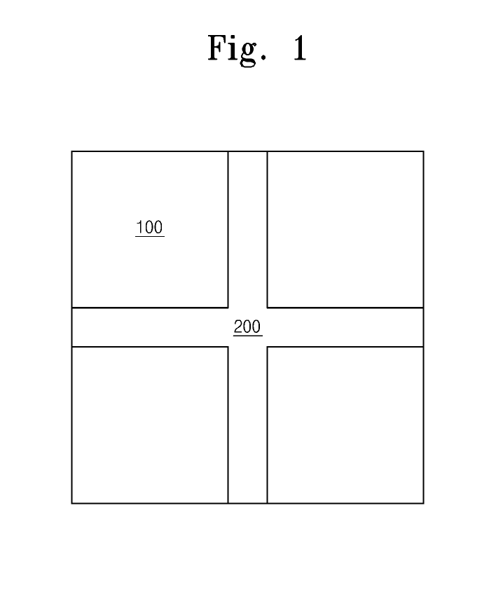

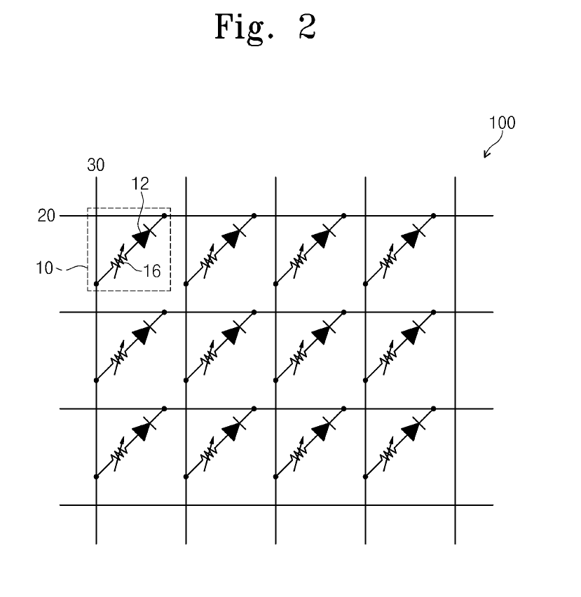

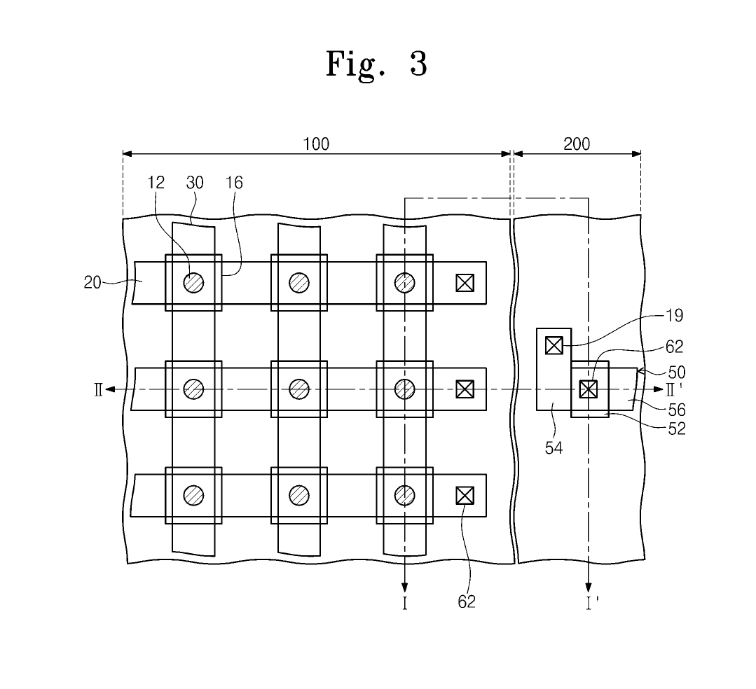

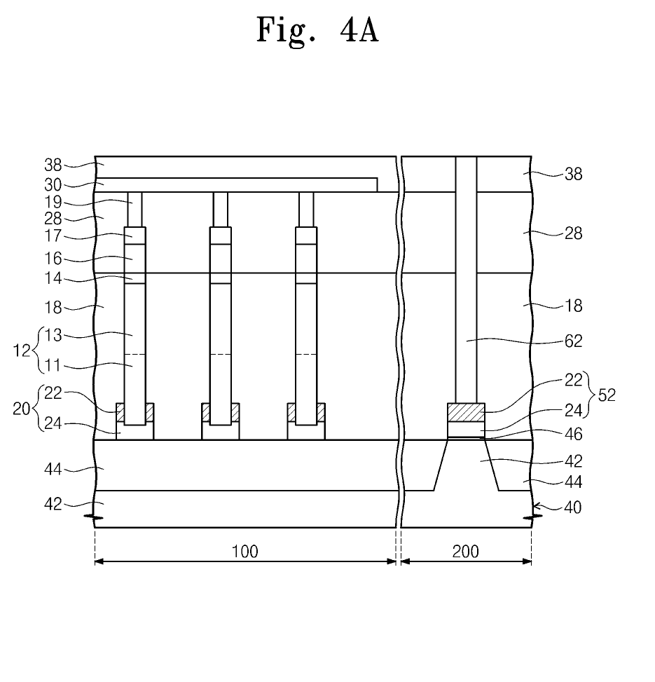

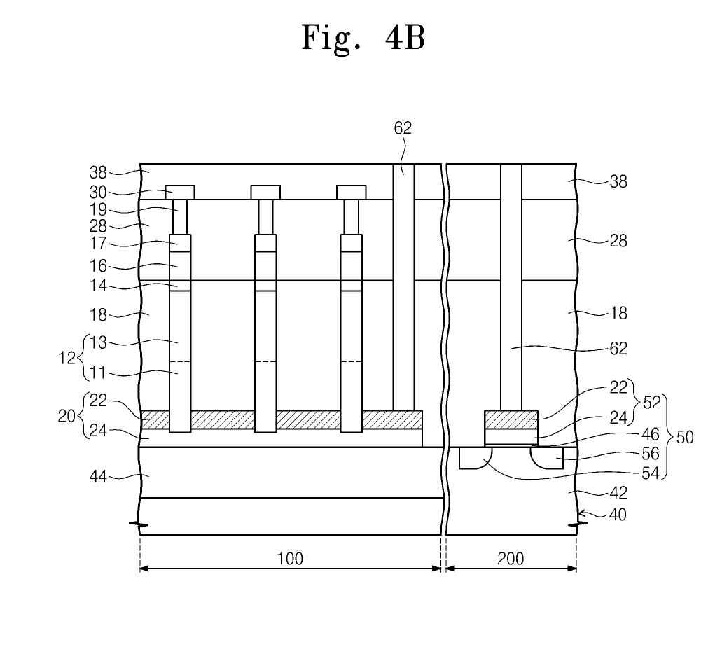

FIG. 1 is a top plan view illustrating a variable resistive memory device in accordance with some embodiments of the inventive concept. FIG. 2 is an equivalent circuit diagram illustrating a cell array in a cell area of FIG. 1. FIG. 3 is a layout of the variable resistive memory device of FIG. 1. FIGS. 4A and 4B are cross sectional views taken along the lines I-I′ and II-IF of FIG. 1 respectively.

Referring to FIGS. 1 through 4B, a memory device in accordance with some embodiments of the present disclosure may include a word line 20 formed in a cell region 100 (see FIG. 2). As shown in FIG. 4B, the word line 20 may be formed of metal having the same level as a gate stack 52 of a transistor 50 formed in a peripheral region 200. The gate stack 52 and the word line 20 may include a polysilicon layer 24 and a first metal layer 22. The word line 20 may be disposed on a device isolation layer 44 of the cell region 100. The gate stack 52 may be disposed on an active region 42 of a substrate 40. The first metal layer 22 may include a metal silicide such as tungsten silicide. The first metal layer 22 may reduce a voltage drop that is in proportion to a length of the word line 20 connected from the peripheral region 200 to phase change memory cells 10 of the cell region 100 (see FIG. 2). Thus, a memory device in accordance an exemplary embodiment of the present disclosure may improve a cell distribution, for example, enabling a larger cell region including additional memory cells connected to a word line.

The transistor 50 may include source/drain regions 54 and 56 formed in the peripheral region 200. The source/drain regions 54 and 56 may be conductive regions such that crystalline silicon of the substrate 40 is doped with a conductive impurity. The source/drain regions 54 and 56 may be disposed in the active region 42 on opposite sides of the gate stack 52. The gate stack 52 may be disposed on a gate insulation layer 46 on the active region 42 of the substrate 40. The gate stack 52 may be electrically connected to a first contact plug 62. The active region 42 between the source/drain regions 54 and 56 may become a channel of the transistor 50. At least one of the source/drain regions 54 and 56 may be electrically connected to a second contact plug 19.

The cell region 100 may be divided by the peripheral region 200 and may be constituted by a plurality of banks. The cell region 100 may include multiple memory cells 10 arranged in a matrix shape defined by a plurality of word lines, e.g., 20 and a plurality of bit lines, e.g., 30. The word lines may extend in a first direction and the bit lines may extend in a second direction. Each of the memory cells 10 may include a diode 12, a lower electrode 14, a phase change resistor 16, and an upper electrode 17. The diode 12 and the lower electrode 14 may be disposed in a mold oxide layer 18.

The diode 12 may be disposed between the word line 20 and the lower electrode 14. The diode 12 may have a PN junction structure. For example, the diode 12 may include a first conductive impurity layer 11 doped with a first conductive impurity and a second conductive impurity layer 13 doped with a second conductive impurity having a conductivity type different than the first conductive impurity. For example, the first conductive impurity may include an n-type donor such as phosphorous or arsenic, and the second conductive impurity may include a p-type acceptor such as boron or gallium.

The lower electrode 14 may be heated by Joule's heat. The Joule heating, also known as ohmic heating and resistive heating, may be in proportion to a current provided from the word line 20 and the diode 12. The lower electrode 14 may be in ohmic-contact with the second conductive impurity layer 13 of the diode 12. The lower electrode 14 may include a second metal layer formed between the phase change resistor 16 and the diode 12. Although not illustrated, the second metal layer may include a metal silicide and a resistance metal layer. The metal silicide may include cobalt silicide or nickel silicide. The resistance metal layer may include a metal nitride having resistivity about 10 to 100 times as large as a resistivity of the metal silicide. For example, the metal nitride may include a titanium nitride, a tantalum nitride, a zirconium nitride or a tungsten nitride.

The phase change resistor 16 may include a chalcogenide compound that may be phase-changed to a crystalline state and an amorphous state depending on a temperature change of the lower electrode 14. The phase change resistor 16 may have a variable resistance having different resistances in the crystalline state and the amorphous state. A state of the phase change resistor 16 may be determined depending on the amount of current provided through the word line 20. The upper electrode 17 may be stacked on the phase change resistor 16. A first interlayer dielectric layer 28 may cover the phase change resistor 16 and the upper electrode 17 on the mold oxide layer 18. A second contact plug 19 may be electrically connected to the upper electrode 17. Also, as shown in FIG. 3, the second contact plug 19 may penetrate the first interlayer dielectric layer 28 and the mold oxide layer 18 to be electrically connected to the source region 54.

The bit line 30 may be electrically connected to the second contact plug 19 on the first interlayer dielectric layer 28. A second interlayer dielectric layer 38 may cover the bit line 30. The first contact plug 62 may penetrate the first and second interlayer dielectric layers 28 and 38 and the mold oxide layer 18 to be electrically connected to the word line 20 of the cell region 100 and the gate stack 52 of the peripheral region 200.

The word line 20 and the gate stack 52 may be electrically separated from each other or may be electrically connected to each other. The word line 20 and the gate stack 52 may include the first metal layer 22 having a resistance about one-tenth or less than that of crystalline silicon doped with a conductive impurity. The first metal layer 22 may reduce a voltage drop in proportion to a length of the word line 20 connected from the peripheral region 200 to memory cells 10 of the cell region 100. Thus, the variable resistive memory device in accordance with an exemplary embodiment of the present disclosure may improve a cell distribution.

A method of manufacturing the variable resistive memory device in accordance with an exemplary embodiment of the present disclosure is described as follows.

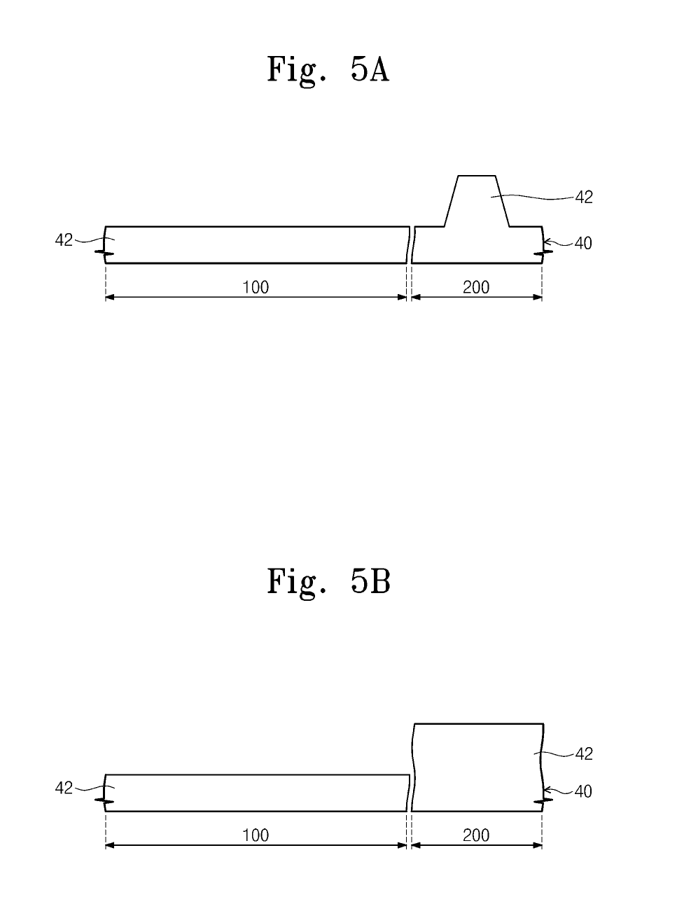

FIGS. 5A through 19A and FIGS. 5B through 19B are cross sectional views illustrating a method of manufacturing the variable resistive memory device having the cross sections of FIG. 4A and FIG. 4B, respectively.

Referring to FIGS. 5A and 5B, the substrate 40 includes the active region 42 of the cell region 100 and the active region 42 of the peripheral region 200. The active region 42 of the cell region 100 may be entirely recessed and the active region 42 of the peripheral region 200 may be partly recessed.

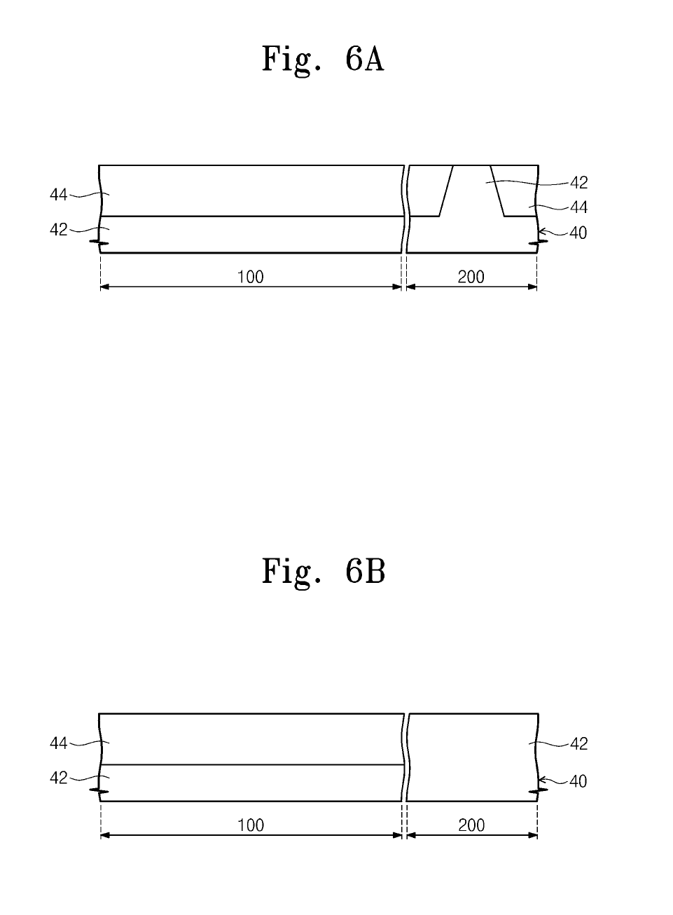

Referring to FIGS. 6A and 6B, a device isolation layer 44 may be formed on an entire surface of the substrate 40 of the cell region 100 and on a part of a surface of the substrate 40 of the peripheral region 200. The device isolation layer 44 may define the active region 42 in the substrate 40 of the peripheral region 200. The device isolation layer 44 may include a silicon oxide formed by a chemical vapor deposition method. The device isolation layer 44 may be planarized to be even with the active region 42 by a chemical mechanical polishing process. Similarly, the device isolation layer 44 and the active region 42 may be planarized to be even with one another.

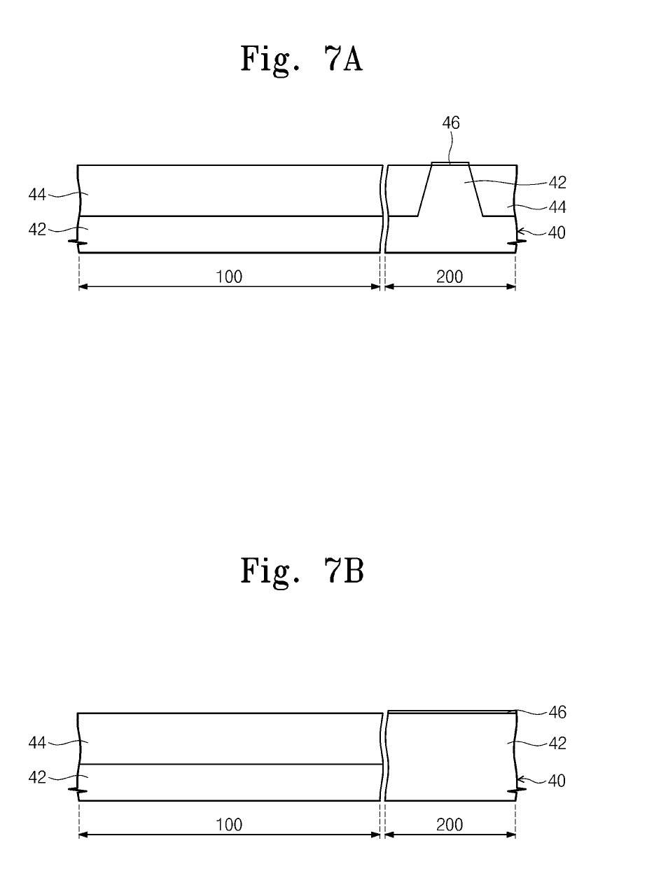

Referring to FIGS. 7A and 7B, a gate insulation layer 46 may be formed on the active region 42 of the peripheral region 200. The gate insulation layer 46 may include a silicon oxide formed by a rapid thermal treatment process. The gate insulation layer 46 may have a thickness of about 30 angstroms (Å) to 100 Å.

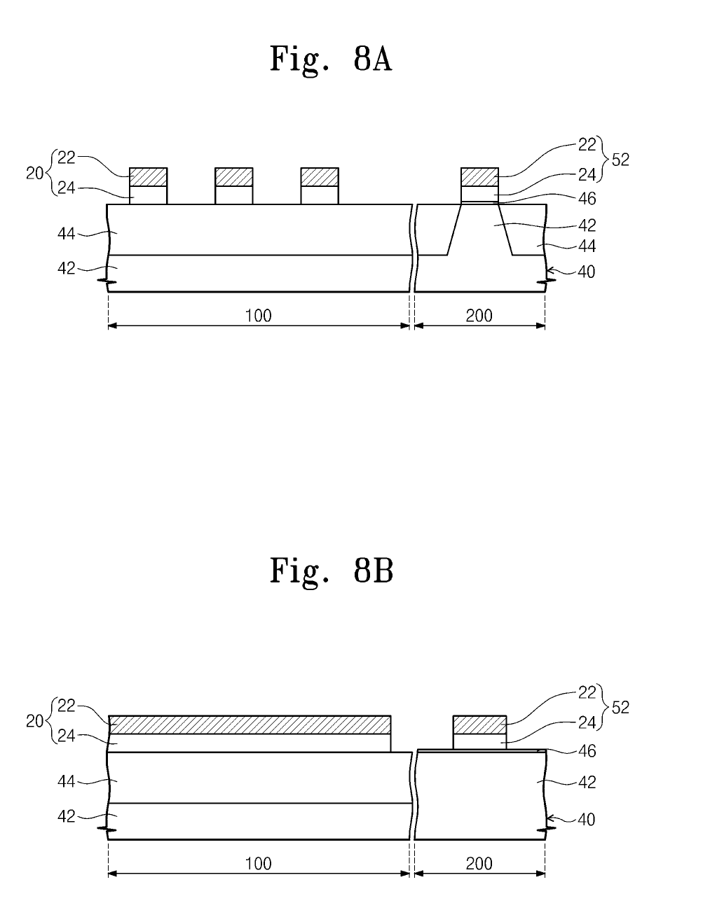

Referring to FIGS. 8A and 8B, a word line 20 may be formed on the cell region 100 and a gate stack 52 may be formed on the active region 42 of the peripheral region 200. The word line 20 and the gate stack 52 may include a polysilicon layer 24 and a first metal layer 22 sequentially formed by a chemical vapor deposition method. The word line 20 and the gate stack 52 may be patterned by a photolithography process. The first metal layer 22 may include metal silicide such as tungsten silicide. Tungsten silicide may have a resistance about one-tenth or less that of crystalline silicon doped with a conductive impurity.

Thus, according to an exemplary method of manufacturing the variable resistive memory device, the word line 20 including the first metal layer 22 may be formed in the cell region 100 and have the same level as the gate stack 52 of the peripheral region 200.

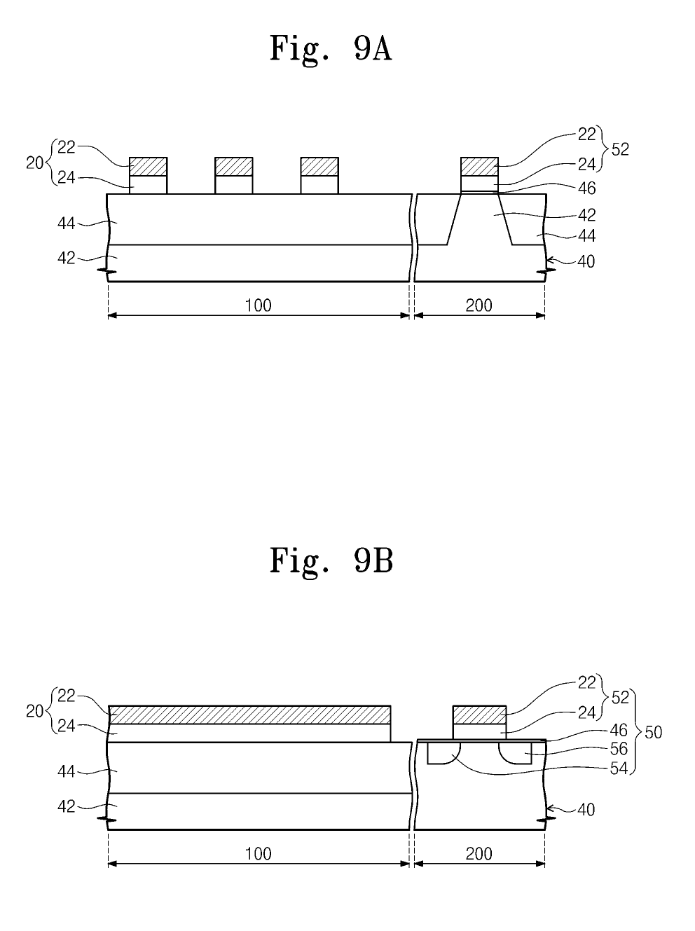

Referring to FIGS. 9A and 9B, source/drain regions 54 and 56 are formed in the active region 42 at opposite sides of the gate stack 52 of the peripheral region 200. The source/drain regions 54 and 56 may be formed by an ion implantation process using the gate stack 52 as an ion implantation mask.

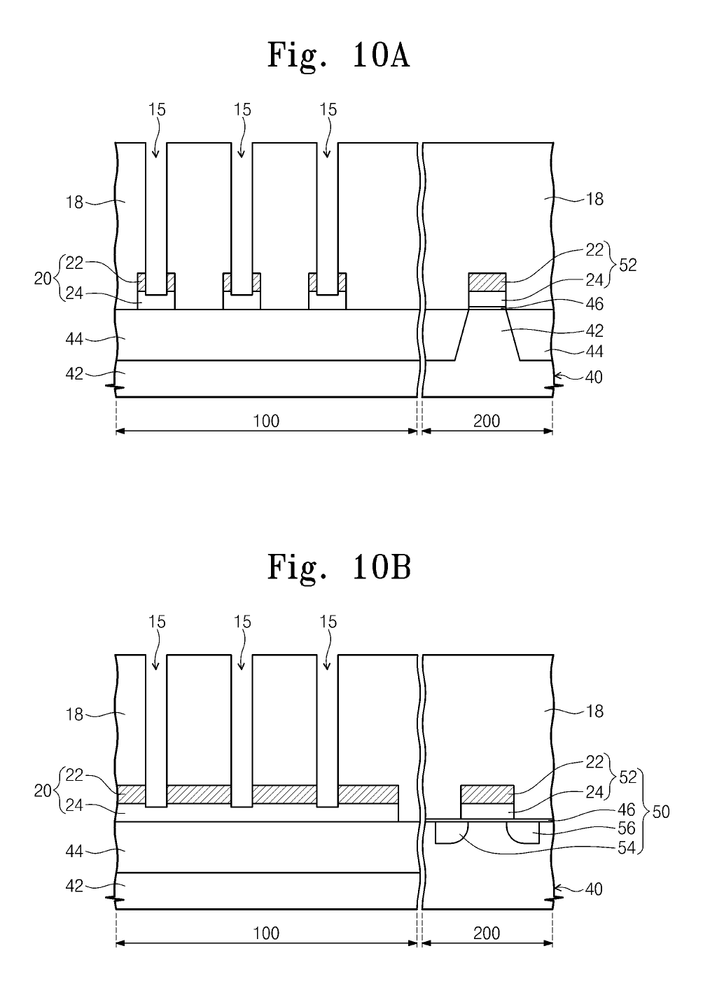

Referring to FIGS. 10A and 10B, a mold oxide layer 18 may be formed having a first contact hole 15 exposing the word line 20. The mold oxide layer 18 may include a silicon oxide formed by at least one of undoped silicate glass (USG), boron-phosphor silicate glass (BPSG), phosphor silicate glass (PSG), boron silicate glass (GSG), spin on glass (SOG), tetraethylorthosilicate (TEOS), plasma enhanced-tetraethylorthosilicate (PE-TEOS), and high density plasma chemical vapor deposition (HDP-CVD). The first contact hole 15 may be formed by a photolithography process. For example, the photolithography process may include a photo process of forming a photoresist pattern exposing a portion of the mold oxide layer 18 on the word line 20 and an etching process of removing the exposed portion of the mold oxide layer 18 using the photoresist pattern as an etch mask. The etching process may be performed until the polysilicon layer 24 of the word line 20 is exposed.

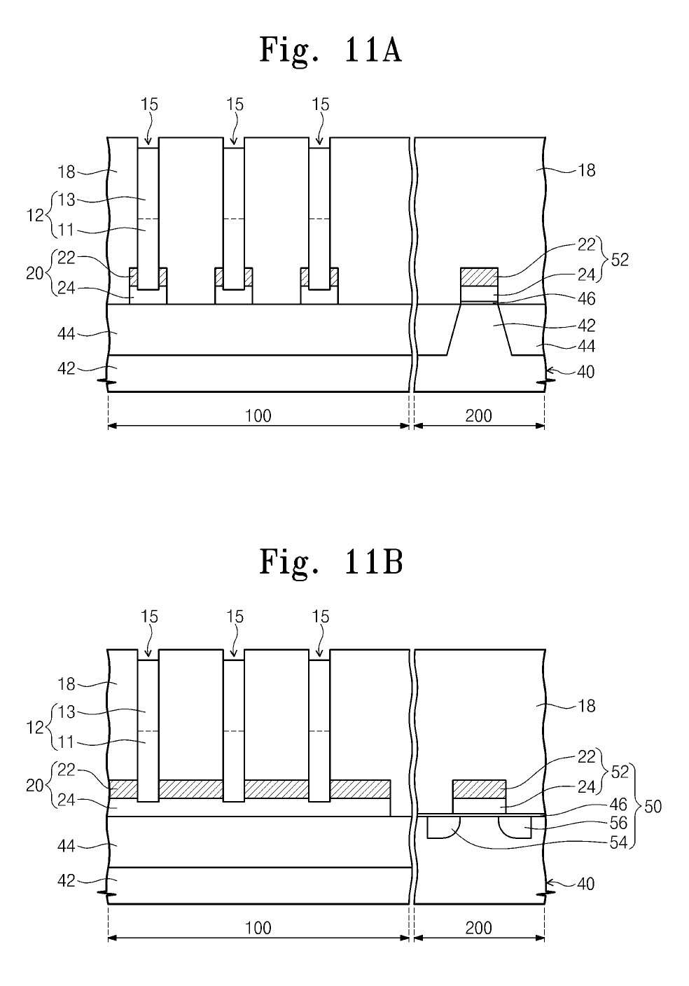

Referring to FIGS. 11A and 11B, a diode 12 may be formed in the first contact hole 15. The diode 12 may include an amorphous silicon layer formed in the first contact hole 15. The amorphous silicon layer may be formed on an entire surface of the substrate 40 by a chemical vapor deposition method. The amorphous silicon layer may be removed on the mold oxide layer 18 and at an upper portion of the contact hole 15 by an etch-back process and may remain at a lower portion of the contact hole 15. A thickness of the amorphous silicon layer may be determined by an etching time in an etch-back process. The amorphous silicon layer may be changed to be a crystalline silicon layer by a thermal treatment process. The first contact hole 15 may be a first trench exposing the word line 20 from the mold oxide layer 18.

The diode 12 may include a first conductive impurity layer 11 and a second conductive impurity layer 13 such that the crystalline silicon is doped with conductive impurities having different conductivity types from one another. The first and second conductive impurity layers 11 and 13 may be doped with first and second impurities, respectively. The first and second conductive impurities may be ion-implanted into the crystalline silicon layer by different energies from each other. For example, the first conductive impurity may include an n-type donor such as phosphorous or arsenic and the second conductive impurity may include a p-type acceptor such as boron or gallium.

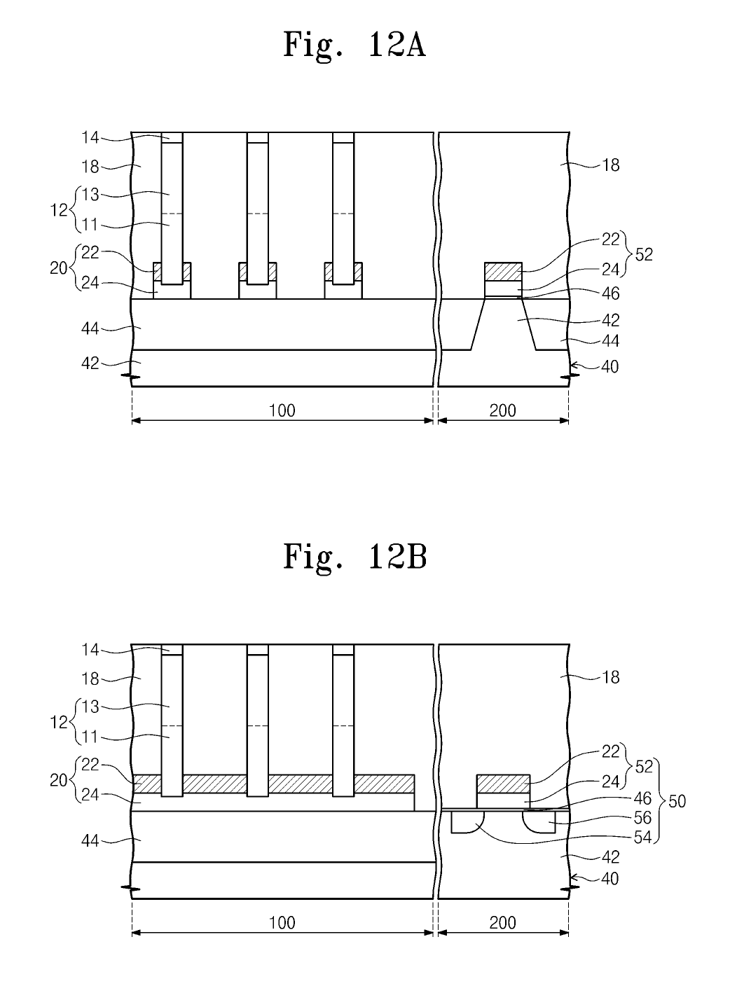

Referring to FIGS. 12A and 12B, a lower electrode 14 may be formed on the diode 12. The lower electrode 14 may be in ohmic-contact with the diode 12 and may have a high resistance. For example, the lower electrode 14 may include a metal silicide and a metal silicon nitride. The metal silicide and the metal silicon nitride may be formed by a chemical vapor deposition method or a sputtering method. The metal silicide may include silicide reaction metal having a lower melting point than that of the metal silicon nitride. The metal silicide may include cobalt or nickel. The metal silicon nitride may be formed by a metal-organic chemical vapor deposition (MOCVD) method. The metal silicon nitride may have a resistivity about 10 to 100 times as large as resistivity of a metal silicide and a metal nitride. For example, the metal silicon nitride may include a titanium silicon nitride, a tantalum silicon nitride, a zirconium silicon nitride and a tungsten silicon nitride. The titanium silicon nitride may be formed by a metal-organic chemical vapor deposition (MOCVD) method using TDMA including titanium nitride and BTBAS including silicon nitride as a source gas. More particularly, the metal silicon nitride may be formed by the metal-organic chemical vapor deposition (MOCVD) method using a source gas having a high temperature of about 200 degrees Celsius (° C.) or more without using a plasma reaction.

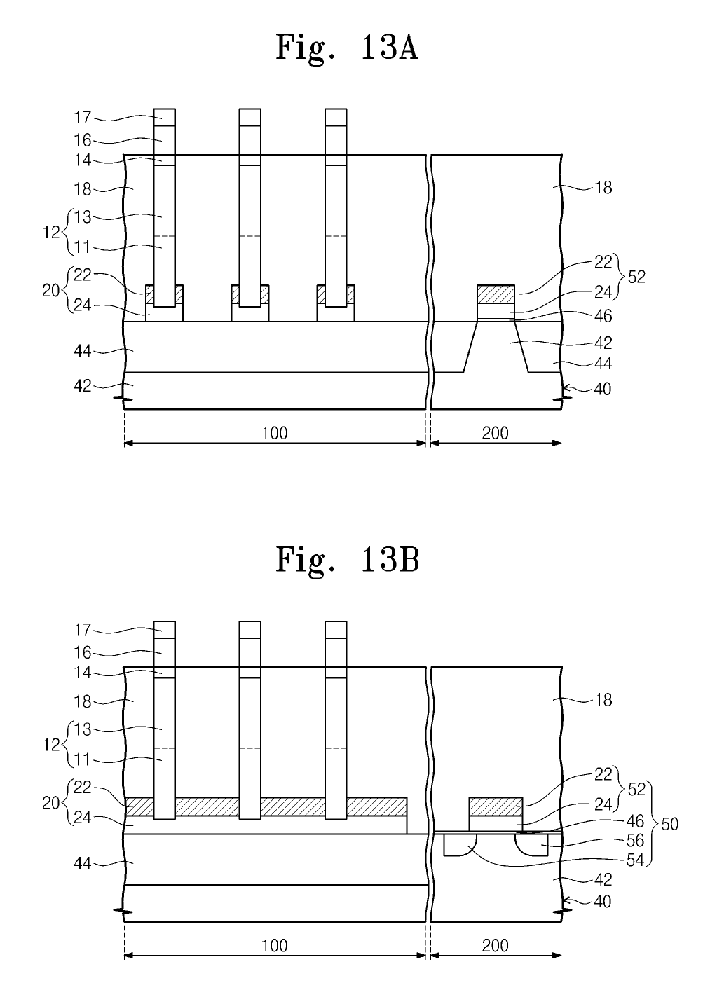

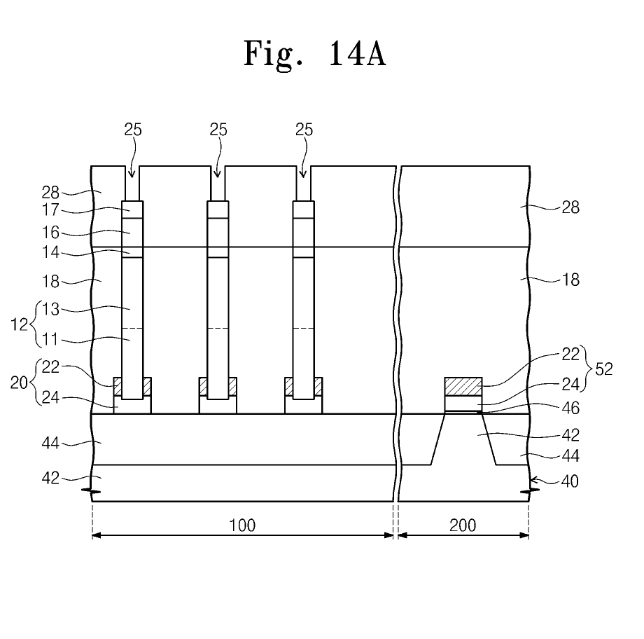

Referring to FIGS. 13A and 13B, a phase change resistor 16 and an upper electrode 17 may be formed on the lower electrode 14. The phase change resistor 16 and the upper electrode 17 may be stacked on the lower electrode 14 by a chemical vapor deposition method and/or a physical vapor deposition method, and a photolithography process. The phase change resistor 16 may include germanium-antimony-tellurium or a chalcogenide compound such that the germanium-antimony-tellurium is doped with carbon, nitrogen, and/or metal. The upper electrode 17 may include at least one metal of titanium, tungsten, aluminum, nickel, zirconium, molybdenum, ruthenium, palladium, hafnium, tantalum, iridium, and platinum. The upper electrode 17 may also include at least one metal nitride of a titanium nitride, a tungsten nitride, an aluminum nitride, a nickel nitride, a zirconium nitride, a molybdenum nitride, a ruthenium nitride, a palladium nitride, a hafnium nitride, a tantalum nitride, an iridium nitride, a platinum nitride, a niobium nitride, a titanium aluminum nitride, a zirconium aluminum nitride, a molybdenum aluminum nitride and, a tantalum aluminum nitride.

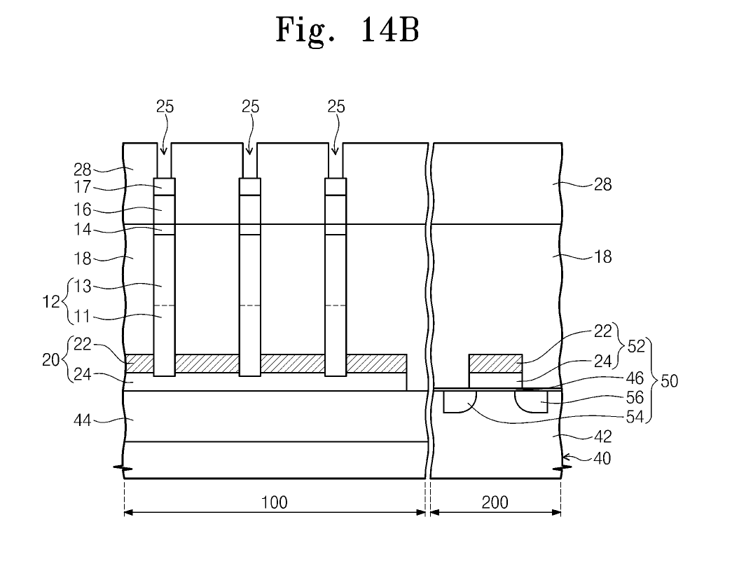

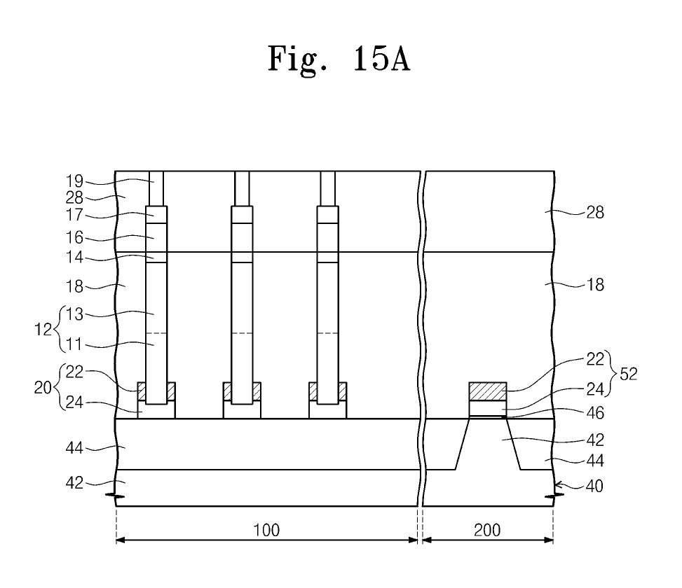

Referring to FIGS. 14A and 14B, a first interlayer dielectric layer 28 may be formed having a second contact hole 25 exposing the upper electrode 17. The first interlayer dielectric layer 28 may be formed of the same silicon oxide as the mold oxide layer 18. The second contact hole 25 may be formed by a photolithography process. The photolithography process may include a photo process of forming a photoresist pattern exposing the first interlayer dielectric layer 28 on the upper electrode 17 and an etching process of removing the first interlayer dielectric layer 28 using the photoresist pattern as an etch mask. The second contact hole 25 is a second trench and may selectively expose the upper electrode 17 from the first interlayer dielectric layer 28. Although not illustrated, the mold oxide layer 18 under the first interlayer dielectric layer 28 may be removed and thereby the source region 54 may be exposed by the second contact hole 25.

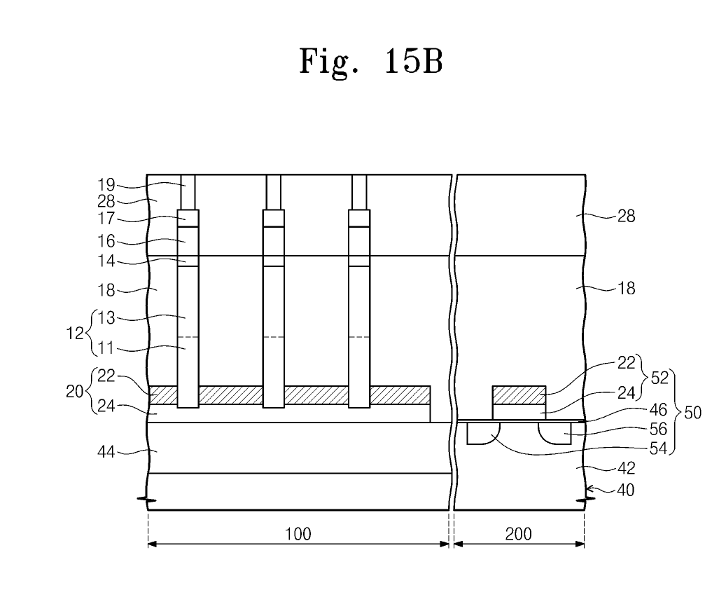

Referring to FIGS. 15A and 15B, a second contact plug 19 may be formed in the second contact hole 25. The second contact plug 19 may include metal such as tungsten, aluminum, copper, tantalum, and titanium. The second contact plug 19 may be formed by filling the second contact hole 25 with a metal layer and performing a planarization process or an etch-back process on the metal layer until the first interlayer dielectric layer 28 is exposed.

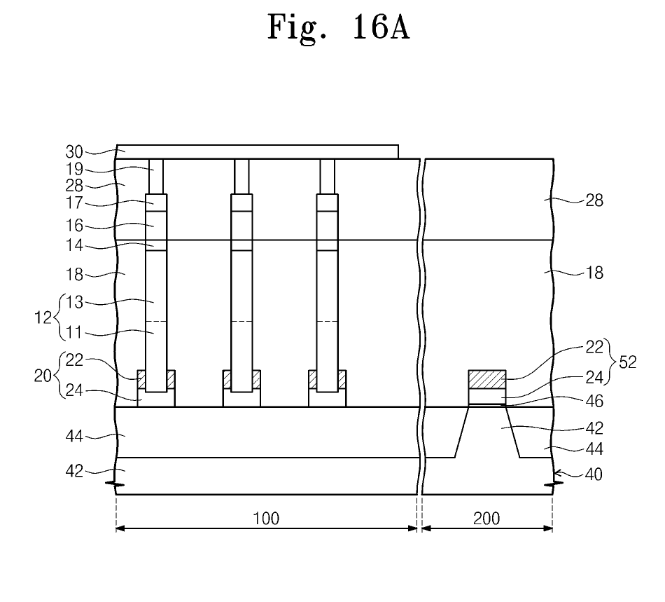

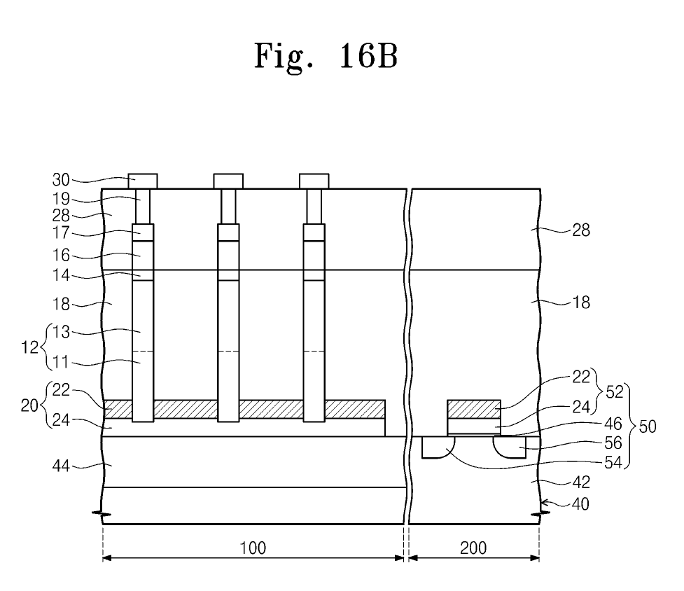

Referring to FIGS. 16A and 16B, a bit line 30 may be formed on the upper electrode 17. The bit line 30 may include a metal material such as tungsten, copper, tantalum, and titanium having a superior conductivity. The bit line 30 may be formed by a process of depositing a metal layer and patterning the metal layer by a photolithography process. The process of depositing the metal layer may be performed by, for example, a sputtering method or a chemical vapor deposition method. The photolithography process may include a photo process for forming a photoresist pattern and an etching process for removing portions of the metal layer using the photoresist pattern as an etch mask.

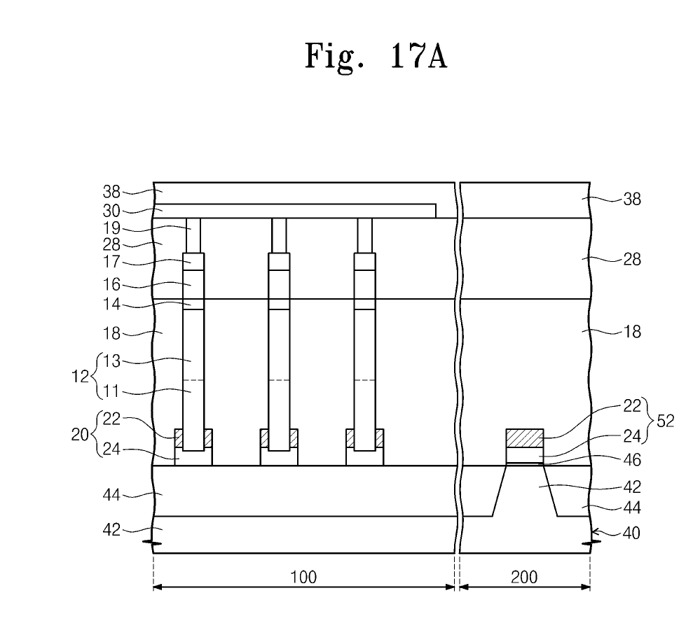

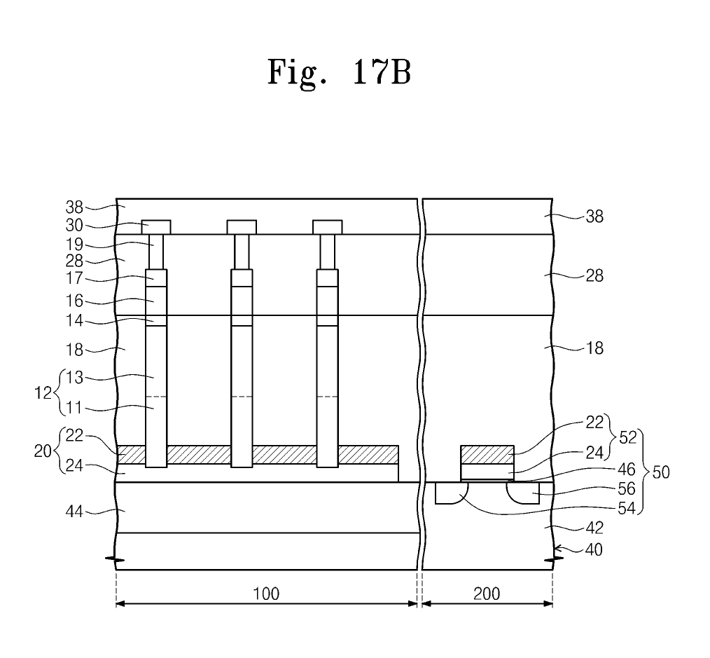

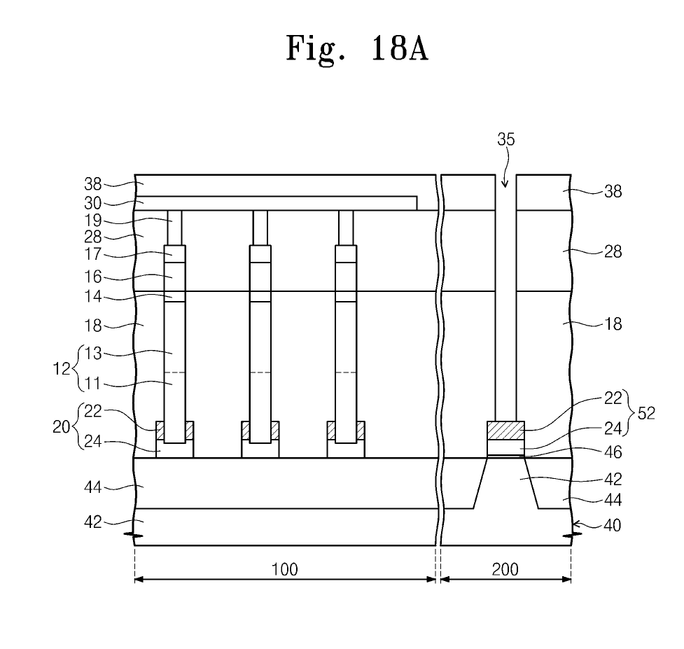

Referring to FIGS. 17A and 17B, a second interlayer dielectric layer 38 may be formed on the bit line 30 and the first interlayer dielectric layer 28. The second interlayer dielectric layer 38 may be formed of the same silicon oxide as the first interlayer dielectric layer 28.

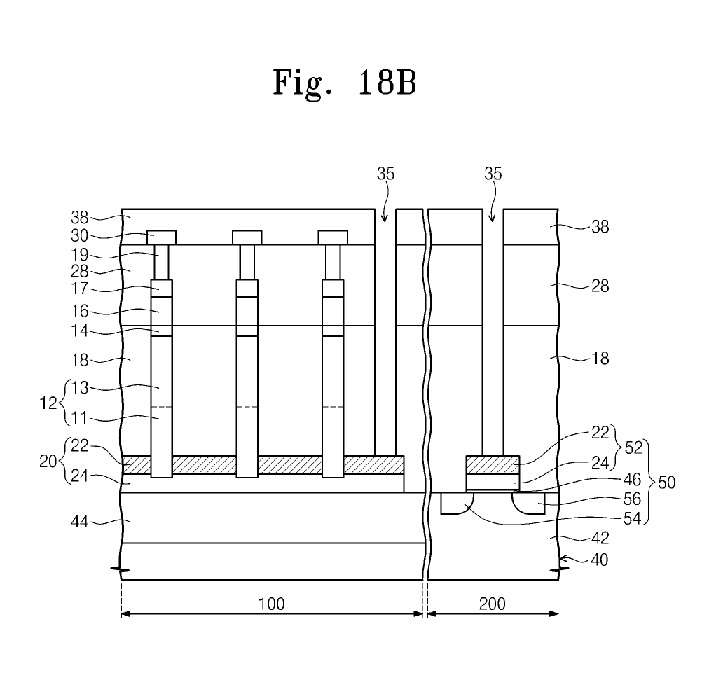

Referring to FIGS. 18A and 18B, third contact holes 35 may be formed by removing portions of the first and second interlayer dielectric layers 28 and 38, and a portion of the mold oxide layer 18 on the word line 20 and the gate stack 52. The third contact holes 35 may expose the word line 20 and the gate stack 52 at the same time. The third contact holes 35 may be formed by a photolithography process. The photolithography process may include a photo process for forming a photoresist pattern exposing portions of the second interlayer dielectric layer 38 and an etching process of removing the first and second interlayer dielectric layers 28 and 38 and the mold oxide layer 18 using the photoresist pattern as an etch mask. Thus, in an exemplary method of manufacturing a variable resistive memory device, the third contact holes 35 simultaneously exposing the word line 20 and the gate stack 52 may be formed by one etching process. The third contact holes 35 may penetrate the first metal layer 22 of the word line 20 to expose the polysilicon layer 24.

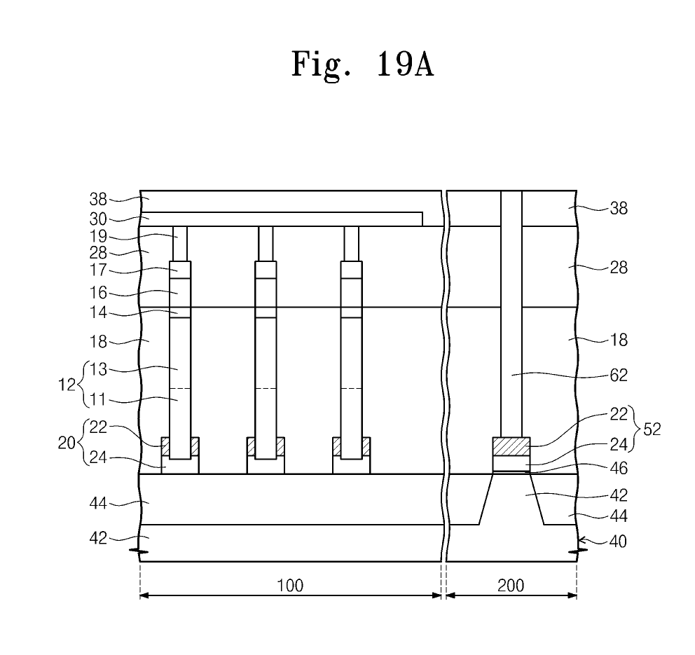

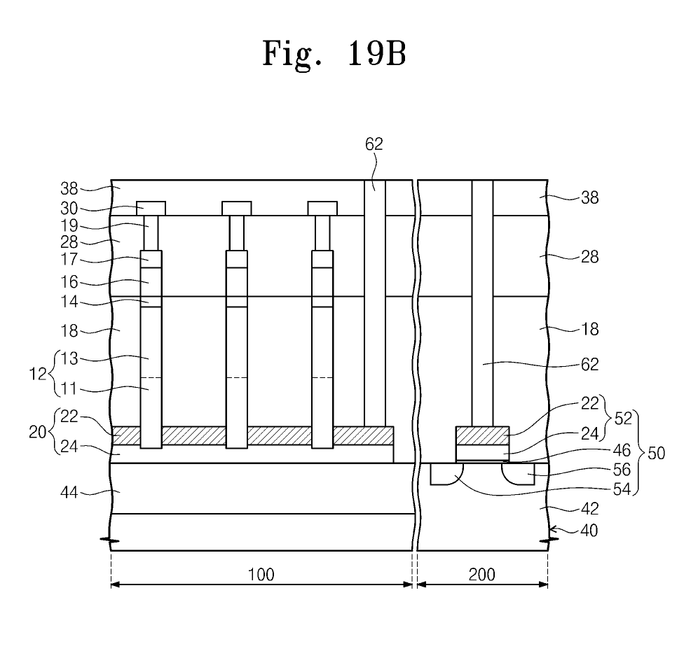

Referring to FIGS. 19A and 19B, first contact plugs 62 may be formed in the third contact holes 35. The first contact plugs 62 may include a direct contact plug. The first contact plugs 62 may be electrically connected to the word line 20 and the gate stack 52. The first contact plugs 62 may include a conductive metal. Although not illustrated, the first contact plugs 62 may be electrically connected by a metal interconnection process.

In an exemplary method of manufacturing a variable resistive memory device, the word line 20 of the cell region 100 and the gate stack 52 of the peripheral region 200 may be simultaneously formed from a same metal layer. Also, the word line 20 and the gate stack 52 may be simultaneously exposed by the third contact holes 35 in first and second interlayer dielectric layers 28 and 38 and the mold oxide layer 18.

As described above, according to an exemplary embodiment of the present disclosure, a cell region may include a word line having a metal layer formed at a same layer as a gate stack of a peripheral region. The word line may reduce a voltage drop in proportion to a distance from the peripheral region. Thus, a variable resistive memory device in accordance with some embodiments of the inventive concept may enable an improved cell distribution.

Although embodiments of the present disclosure have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

1. A variable resistive memory device comprising:
a substrate comprising a cell region and a peripheral region;
a word line extending in a first direction formed on the substrate of the cell region;
a switching element formed on the word line;
a variable resistance layer formed on the word line; and
at least one transistor comprising a gate stack, the gate stack formed on the substrate of the peripheral region,
wherein the word line comprises a metal layer formed at a same level as the gate stack.

2. The variable resistive memory device of claim 1, further comprising a device isolation layer formed between the word line and the substrate.

3. The variable resistive memory device of claim 1, further comprising a device isolation layer defining an active region of the substrate including source/drain regions of the transistor in the peripheral region.

4. The variable resistive memory device of claim 1, wherein the metal layer comprises metal silicide.

5. The variable resistive memory device of claim 1, wherein the word line further comprises a polysilicon layer beneath the metal layer, and the gate stack comprises the metal layer and the polysilicon layer beneath the metal layer.

6. The variable resistive memory device of claim 1, further comprising:
a mold oxide layer formed on the word line; and
an interlayer dielectric layer formed on the mold oxide layer and the variable resistance layer.

7. The variable resistive memory device of claim 6, further comprising:
a first contact plug penetrating the mold oxide layer and the interlayer dielectric layer to be connected to the word line; and
a second contact plug penetrating the mold oxide layer and the interlayer dielectric layer to be connected to the gate stack.

8. The variable resistive memory device of claim 6, further comprising a bit line electrically connected to the variable resistance layer in the interlayer dielectric layer, the bit line extending in a second direction crossing the word line.

9-15. (canceled)

16. A variable resistive memory device comprising:
a substrate comprising a cell region and a peripheral region;
a word line formed on the substrate of the cell region;
a plurality of phase change memory cells connected to the word line; and
at least one transistor comprising a gate stack, the gate stack formed on the substrate of the peripheral region,
wherein the word line and the gate stack are formed of different portions of a same metal layer.

17. The variable resistive memory device of claim 16, further comprising a gate insulation layer disposed between the gate stack and the substrate.

18. The variable resistive memory device of claim 16, further comprising a device isolation layer defining an active region of the substrate including source/drain regions of the transistor in the peripheral region.

19. The variable resistive memory device of claim 16, wherein the metal layer comprises metal silicide.
